(19) United States
(12) Patent Application Publication
(10) Pub. No.: US 2004/0154748 A1
(43) Pub. Date: Aug. 12, 2004

(54) Electrostatic clamping of thin wafers in plasma processing vacuum chamber

(76) Inventors: Paul Rich, Gloucestershire (GB); Clive Luca Widdicks, Bristol (GB)

Correspondence Address: VOLENTINE FRANCOS, PLLC, Suite 150, 12200 Sunrise Valley Drive, Reston, VA, 20191, US

(21) Appl. No.: 10/760,464

(22) Filed: Jan. 21, 2004

Related U.S. Application Data
(60) Provisional application No. 60/445,459, filed on Feb. 7, 2003.

(51) Int. Cl. H01L 21/306; C23C 16/00; C23C 14/00

(52) U.S. Cl. 156/345.51; 204/298.15; 118/728; 204/298.11

(57) ABSTRACT

Apparatus and methods of processing a substrate having a thickness of 250 microns or less are described. Each use a dark space shield between the plasma in a process chamber and the periphery of the substrate to prevent the presence of plasma between the shield and the periphery whilst allowing processing of the substrate. In every case an electrostatic chuck is utilised.

The plasma processing of substrates such as semiconductor wafers is well known, as is the requirement for the thermal control of such substrates, frequently by electrostatically clamping them to a thermally controlled electrode or pedestal.

Silicon wafers are typically supplied to an industry standard thickness that ensures they are rigid and relatively strong mechanically. The thickness of the wafer is related to crystallography and wafer size, and by way of guidance is presently 400 microns or more for a 100 mm wafer and 675 microns or more for a 150 mm wafer. Such wafer thickness however has disadvantages for use in certain applications including power devices (where heat may be dissipated through the thickness of the wafer), small consumer electronic devices (where small thin packaged devices are desirable), packages containing stacked devices and certain micro electro mechanical (MEMs) devices.

There is therefore a requirement to be able to process thin wafers where either a standard thickness wafer is at least part processed (e.g. on their front side) and then thinned prior to further processing, or thin wafers may be used throughout the wafer processing. Thin is not defined within the industry but would generally be understood as less than half the original thickness, or about 250 microns as an upper limit. As the technology of thinning and processing such wafers develops the thickness of a ‘thin’ wafer is reducing such that presently 150-100 microns might be considered a ‘typical thin’ wafer and 50 microns or less considered ultra thin. Processing of thin wafers produces significant challenges since these substrates are liable to bow significantly, particularly if one face or surface is put into tension or compression with respect to the other. This may happen if one side is heated, has material deposited upon it or material removed. As all these effects are likely within a wafer plasma processing system, there is a high probability that bending or bowing will occur. This can in turn lead to problems in wafer transport.

In particular, in order to minimise film stress (and hence reduce wafer bow) it can be helpful to maintain the wafer temperature close to ambient room temperature during a sputter deposition process. Electrostatic clamping is a well known method of bringing the wafer into close contact with a chuck to enable gas to pressurise the space between wafer and chuck. This enables good thermal conduction during deposition. It has however been found that thin wafers are very prone to clamping failure possibly leading to complete de-chuck during the deposition sequence. A solution is provided here.

The Applicants have determined that the failure mechanism is as follows. During the processing a stress load e.g. heat is applied preferentially to one side of the wafer. This causes the wafer to try and curl or bow. The clamping force exerted electrostatically will in turn try and keep the thin wafer flat upon the chuck. If, however, the wafer starts to peel away from the chuck then the clamping force is quickly lost from the edge of the wafer leading to complete failure of the clamping. This peeling effect is exacerbated by the presence of plasma at the edge of the wafer because a gas plasma is electrically conductive. This conductivity will leak charge from the backside edge of the wafer. As the thin wafer starts to bow and lift at the edges, the charge leakage from the backside of the wafer to the plasma will disable the clamping force. This allows the wafer to pull further from the chuck under the process-induced stress causing further charge loss from the wafer. Eventually this leads to complete clamping failure.

In practice a plasma can only be at the backside of the wafer during processing if the edge and backside edge of the wafer is exposed to a plasma.

From one aspect the invention consists in apparatus for processing a substrate having a thickness of less than 250 micron, including a chamber, plasma creation element or elements for creating a plasma in a zone of the chamber and an electrostatic chuck for retaining a substrate at a substrate location in or adjacent the zone characterised in that the apparatus further includes a dark space shield disposed on the zone side of the chuck circumjacent or overlying the periphery of the location to substantially prevent the presence of plasma between the shield and the periphery of the substrate whilst allowing processing of the substrate.

‘Substantially prevent’ means that the dark space shield suppresses a plasma sufficiently for the electrostatic clamping to remain effective throughout the processing of the thin wafer wherein, without a shield, the clamping would fail for the same process and wafer.

In a preferred embodiment the shield is generally annular and it will be understood that it is in any event open so that the substrate is substantially exposed to the plasma. It will be further understood that the substrate location may extend beyond the support surface of the electrostatic chuck as is specifically described below.

The shield may be electrically conducting and may be electrically grounded of floating potential or connected to a plasma creating electrode, or antenna where it may be at the same potential as that electrode. The chuck may itself be a plasma creating element, in which case it may be powered.

From another aspect the invention consists in a method for processing a substrate having a thickness of less than 250 micron including electrostatically clamping the substrate to a chuck, creating a plasma adjacent the outwardly facing face of the clamped substrate and locating a dark space shield between the plasma and the periphery of the substrate to prevent the presence of plasma between the shield and the periphery whilst allowing processing of the substrate.

Preferably the shield overlies the periphery, but it may extend circumjacent to the periphery.

In a particularly preferred embodiment the substrate thickness may be less than or equal to 100 microns.

For the purposes of this specification a “dark space shield” is any spaced physical element, which prevents the formation of a plasma between the shield and the substrate by virtue of its physical proximity. The dimensions of the spacing relate to the mean free path of the plasma forming ions and that hence are determined by such factors as frequency of applied plasma power, gas, pressure and power density. In most arrangements, particularly where higher frequencies are used, it may be necessary to ground the shield to achieve the dark space reliably over the processing of many wafers and therefore a grounded dark space shield is most preferred, but not necessary for operation of this invention.

Thus in the case of a wafer, a dark space shield is placed between the plasma and the wafer and preferably has an internal diameter slightly smaller than the wafer itself. This is apparatus is particularly useful for deposition processes where the build up of deposited material about the wafer location makes potential alternative solutions impracticable for production use.

In the prior art other solutions have been attempted, though not specifically for thin wafers. In GB 0216711.2, the Applicants utilised a dished chuck as a solution for the continued clamping of wafers as the bowed as a result of asymmetric stress. The wafer as it bowed relaxed into the dishing of the chuck. The Applicants have also noted U.S. Pat. No. 6,117,349 that discloses (as prior art) a dielectric shadow ring about the peripheral part of a wafer as part of a structure to isolate an electrostatic chuck from the plasma of an etch chamber. In isolating the chuck (not any part of the wafer) from the plasma a shadow ring 12 is disclosed as known in the art and an improved 2-part shadow ring invented. It will be noted that the shadow ring still does not prevent plasma from entering gap 52 about the periphery of the wafer evidenced by its attacking surface 44 now contained upon a sacrificial ring part 56.

Although the invention has been defined above it is to be understood it includes any inventive combination of the features set out above or in the following description.

The invention may be performed in various ways and specific embodiments will now be described, by way of example, with reference to the accompanying drawings, in which:

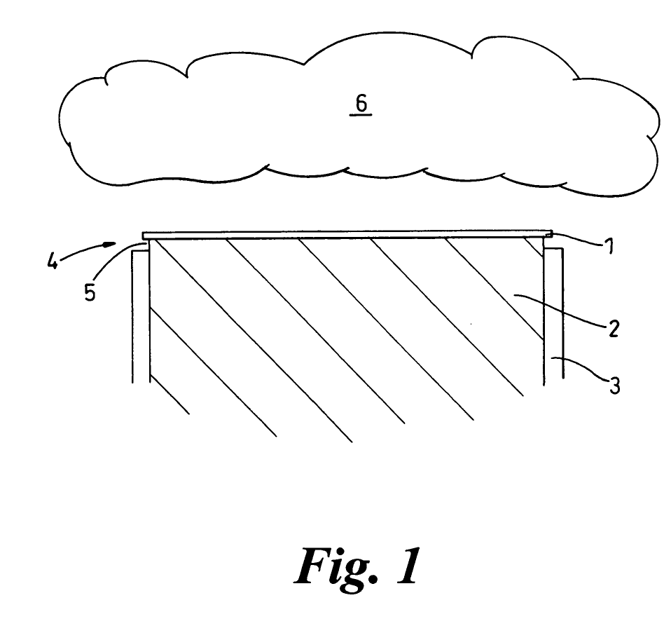

FIG. 1 is a schematic representation of a prior art electrostatic chuck/plasma configuration;

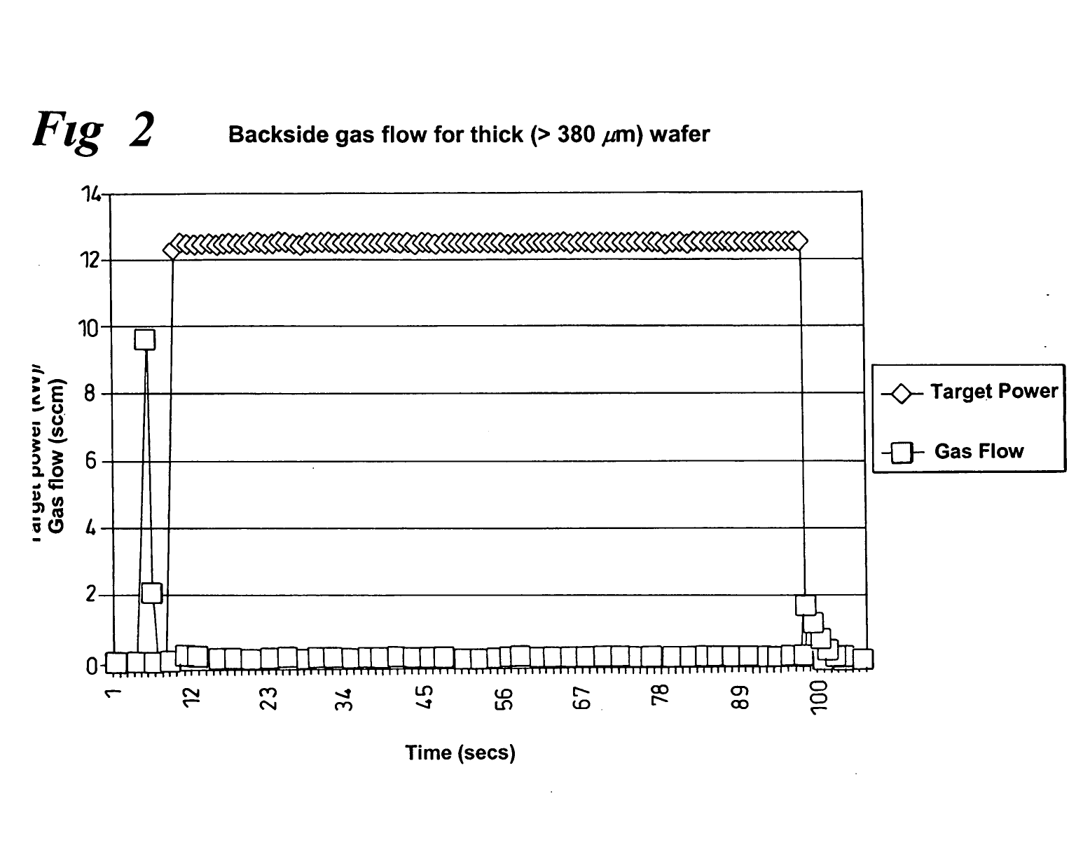

FIG. 2 is a graph indicating wafer backside gas leakage from the FIG. 1 arrangement when a thick wafer is held by the chuck during a sputtering process;

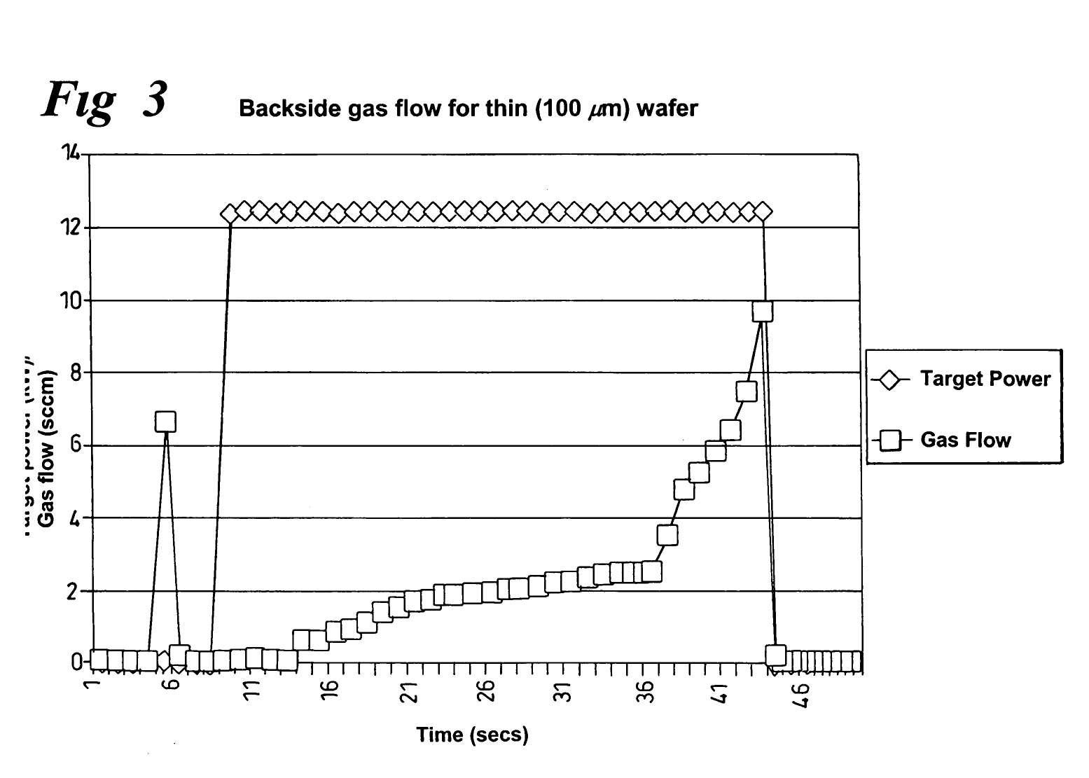

FIG. 3 indicates the same arrangement with a thin wafer;

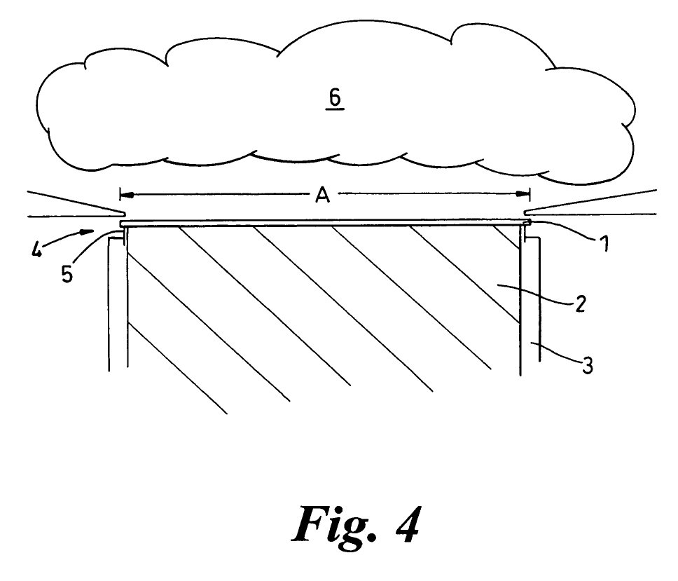

FIG. 4 is a schematic representation of an embodiment of the Applicant's proposal including a dark space shield;

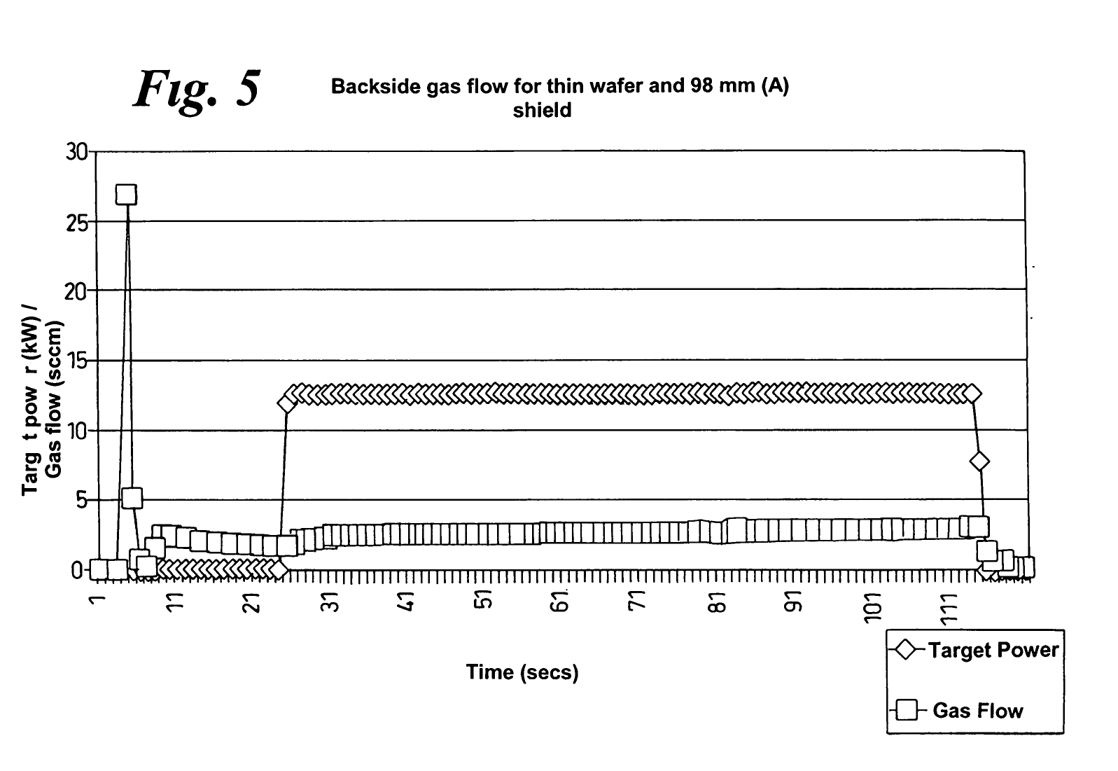

FIG. 5 is a graph of wafer backside gas leakage for the FIG. 4 embodiment during sputtering with thin wafer; and

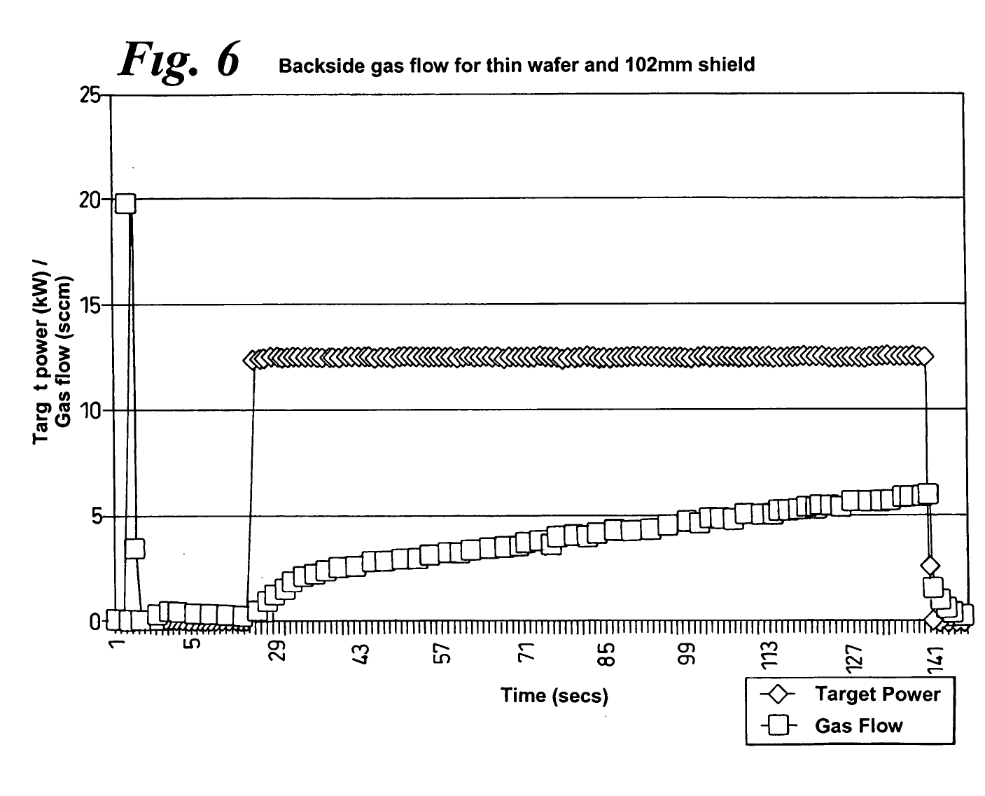

FIG. 6 is the corresponding graph where the dark space shield has an inner diameter which is slightly larger than the outer diameter of a thin wafer.

FIG. 1 (prior art) shows a basic arrangement of an electrostatic chuck and wafer in a sputtering system. A wafer 1 sits upon electrostatic chuck 2 with a replaceable shield 3 about it to prevent deposition material build up on the chuck. The gap 4 is required in, e.g. a production sputtering system, to allow the build up of material about the wafer without interfering with the seating of wafers upon the chuck. It should be appreciated that to ensure long operational times without maintenance it should be possible to deposit many microns of material from the target without intervention. For this reason this gap is large in relation to the thickness deposited upon each wafer. Semiconductor wafers have various flats or notches for rotational alignment and these differ from wafer types and wafer sizes. To avoid exposing the top of the chuck at the flat or notch the wafer generally overhangs the chuck to some degree as shown at 5. For a 100 mm wafer this overhang is typically 3 mm (i.e. a 94 mm diameter chuck). This exposes the backside edge of the wafer. A plasma is present generally as indicated at 6 e.g. from a sputter target magnetron.

In such a design problems occur with thin wafers unclamping from the chuck 2. This only occurs when a plasma process is run. Without plasma activity no problems are seen.

FIGS. 2, 3, 5, and 6 are graphs showing flow of wafer backside pressurisation gas in different circumstances. Flow indicates leakage from between the wafer and the chuck. De-chucking is characterised by a large increase to the backside gas flow. The initial spike in gas flow is due to the gas pressuring the backside of the wafer.

In FIG. 2 (prior art) is seen the wafer backside pressurisation gas flow during a sputter process on a wafer of more than 380 micron thickness with approximately 12 kW of applied power and apparatus as illustrated in FIG. 1. The plasma generates a heat load upon the wafer and also creates a plasma in the vicinity of the wafer. No de-chucking of the wafer is evident and good thermal conductivity of wafer to chuck is maintained. The edge and backside edge of the wafer is exposed. However, due to the stiffness of the wafer the thermal load does not cause significant wafer bowing.

In FIG. 3 (prior art) a thin wafer of approximately 100 microns thickness is processed under the same heat load with the same plasma present in the same apparatus. Here can be seen from the flow of gas that wafer de-chucking has taken place. As a result the thermal conductivity between the wafer and the chuck will be poor and the wafer may be moved, increasing the risk of mishandling by the robot handling system generally present in such single wafer sputtering systems.

It can be seen that within a few seconds of the target turning on with these thin wafers (100 μm), backside gas leakage starts to increase significantly and continues to rise until the leakage reaches a pre-determined level (defined in software) and the system is shut down. From observation of the wafer during deposition, it is clear that the wafer starts to lift at the very edge of the chuck and then peels gradually. The failure mode is believed to be a local discharge of the wafer at its backside edge through the plasma. This causes the clamping force to reduce locally at the very edge of the wafer. The force from the backside pressure combined with the locally weak clamping causes the wafers to peel up at the very edge and eventually to loose backside gas pressurisation.

Dark space shielding was added at the edge of the wafer in an attempt to inhibit local discharge via the plasma. FIG. 4 shows this new apparatus. A generally annular dark space shield 7 of slightly smaller inner diameter A than the outer diameter of the wafer was placed between the wafer 1 and the sputter target to shield the edge of the wafer 1 from the plasma 6. This additional shielding was found to be effective with stable backside gas pressurisation recorded even on thin wafers. The previously mentioned overhang of the wafer 1 is still present and this means that the wafer location diameter is, still greater than that of the chuck presenting a high risk of wafer declamping.

FIG. 5 demonstrates the result for a 98 mm internal diameter (distance A) dark space shield and 100 mm wafer. An additional delay was introduced between electrostatic clamping of the wafer and the target (plasma and heat load) turn on to assist in identifying the effectiveness of the shielding. As can be seen, virtually no change in gas leakage occurs as a result of the target turning on. The slightly higher gas leakage throughout this experiment compared to FIG. 2 that is seen during this run is an expected variation in clamping performance on a wafer-to-wafer basis. The amount of gas leakage is dependent on precise backside finish of the substrate.

To demonstrate that the shielding is effective in stopping the plasma reaching the edge of the wafer a shield of slightly larger inner diameter than the outer diameter wafer was then tried and the clamping performance investigated. FIG. 6 shows data from a 102 mm inner diameter shielding and 100 mm wafer.

FIG. 6 shows that if the shield is larger than the wafer then gas leakage increases significantly during the deposition sequence. This is believed to be because of charge leakage from the wafer as it lifts from the electrostatic chuck under the thermal stress imposed by the process. As the wafer lifts cooling effectivity is lost and the edge of the wafer that is not clamped starts to increase in temperature, causing further bowing. The longer the process duration the greater this effect until total clamping failure results. Shielding of slightly larger diameter than the wafer (FIG. 6) may provide satisfactory performance providing the plasma processing time is not too long. There is demonstrable improvement over no shield being present as evidenced by FIG. 3 where complete clamping failure started to occur at 37 seconds.

It will be understood that the plasma may be struck in any suitable manner. For example an external coil or coils may be used or, additionally or alternatively, electrodes within the chamber may create the plasma, in which case the chuck may be one of the electrodes. It will be understood that the dark space shielding may have a shape that is determined by the substrate shape in terms of cross-section of the opening. The upper surface of the shield is shown as being inclined, but other top surfaces could be utilised. The shield may be movable relative to the chuck to assist with placing and removal of the wafer and it may be attached to the chamber or otherwise supported. It can conveniently be made of metal, but it may also be a non-conducting body, for example it may be formed of ceramic.

The processes performed can be any which require the presence of a plasma and include plasma assisted chemical vapour deposition, sputtering and etching, although the need for the wafer overhang which greatly increases the problem of wafer declamping mainly arises in deposition processes.

1. Apparatus for processing a substrate having a thickness of 250 microns or less, including a chamber, plasma creation element or elements for creating a plasma in a zone of the chamber and an electrostatic chuck for retaining a substrate at a substrate location in or adjacent to the zone characterised in that the apparatus further includes a dark space shield disposed on the zone side of the chuck circumjacent or overlying the periphery of the location for preventing the presence of plasma between the shield and the periphery of a substrate in the location whilst allowing processing of the substrate.

2. Apparatus as claimed in claim 1 wherein the shield is generally annular.

3. Apparatus as claimed in claim 1 or claim 2 wherein the shield is electrically conducting.

4. Apparatus as claimed in claim 3 wherein the shield is grounded.

5. Apparatus as claimed in any one of the preceding claims wherein the chuck is also a plasma creating element.

6. Apparatus as claimed in any one of the preceding claims wherein the chuck is powered.

7. A method for processing a substrate having a thickness of 250 microns or less including electrostatically clamping the substrate to a chuck, creating a plasma adjacent the outwardly facing face of the clamped substrate and locating a dark space shield between the plasma and the periphery of the substrate to prevent the presence of plasma between the shield and the periphery whilst allowing processing of the substrate.

8. A method as claimed in claim 2 wherein the substrate thickness is less than or equal to 100 microns.
